(19) United States
(12) Patent Application Publication
(10) Pub. No.: US 2023/0097454 A1
(43) Pub. Date: Mar. 30, 2023

(54) METHOD FOR LEARNING EXERCISE POSTURE BASED ON USER'S JOINT FEATURE POINT, METHOD FOR ANALYZING EXERCISE POSTURE, AND APPARATUS FOR PERFORMING THE SAME

(71) Applicant: Electronics and Telecommunications Research Institute, Daejeon (KR)

(72) Inventors: Jong Sung KIM, Daejeon (KR); Seong Il YANG, Daejeon (KR); Min Sung YOON, Daejeon (KR); Si Hwan JANG, Daejeon (KR)

(21) Appl. No.: 17/873,430

(22) Filed: Jul. 26, 2022

(30) Foreign Application Priority Data
Sep. 27, 2021 (KR) 10-2021-0127300

(51) Int. Cl. G06T 7/73

(52) U.S. Cl. CPC G06T 7/73; G06T 2207/20081; G06T 2207/30196; G06T 2207/20084; G06T 2207/30221

(57) ABSTRACT

According to an embodiment of the present disclosure, a method for learning an exercise posture of a user is disclosed. The method includes: checking joint feature point information which is constructed based on a joint of the user; learning a ready posture learning model by learning the joint feature point information corresponding to a ready posture of the user; and learning an exercise posture learning model by learning the joint feature point information corresponding to an exercise posture of the user.

### CROSS REFERENCE TO RELATED APPLICATION

The present application claims priority to a Korean patent application 10-2021-0127300, filed Sep. 27, 2021, the entire contents of which are incorporated herein for all purposes by this reference.

### BACKGROUND OF THE INVENTION

### 1. Field of the Invention

The present disclosure relates to a method and apparatus for analyzing a user's exercise action based on an image, and more particularly, to a method and apparatus for analyzing an exercise action by using the joint feature points of a user.

### 2. Description of Related Art

The technology for analyzing the exercise actions of humans is being implemented by various techniques in many fields such as the production of animated films based on humans' exercise actions and motion recognition game consoles as well as the analysis of exercise actions or sports actions like golf swing postures, and a technique using an inertia sensor, a technique using a reflective marker, and a video analysis technique are representative ones.

A technique using an inertia sensor or a technique using a reflective marker has an advantage of sensing a user's exercise actions with high accuracy but also has a fatal disadvantage that many sensors or markers should be attached to the user's body in order to analyze the user's exercise actions, so that these techniques are used only in a very limited situation where the discomfort of attaching sensors or markers to a user's body is not problematic with a view to analyzing the user's exercise actions.

### SUMMARY

Furthermore, there has been an attempt to detect a user's feature points by using an image data and to analyze the user's exercise actions based on the feature points, but in order to analyze the user's exercise actions, various actions of the user need to be analyzed in consideration of various exercise types, which causes the burden of a lot of computational resources, storage media and a large amount of data.

A technical object of the present disclosure is to provide a method and apparatus for analyzing a user's exercise actions quickly and accurately without using many computational resources, storage medium or a large amount of data.

The technical objects of the present disclosure are not limited to the above-mentioned technical objects, and other technical objects that are not mentioned will be clearly understood by those skilled in the art through the following descriptions.

According to an embodiment of the present disclosure, there is provided a method for learning an exercise posture of a user. The method comprising: checking joint feature point information which is constructed based on a joint of the user; learning a ready posture learning model by learning the joint feature point information corresponding to a ready posture of the user; and learning an exercise posture learning model by learning the joint feature point information corresponding to an exercise posture of the user.

According to another embodiment of the present disclosure, there is provided a method for checking an exercise posture of a user. The method comprising: checking joint feature point information that is constructed based on a joint of the user; detecting a ready posture of the user by using a ready posture learning model; and detecting, in consideration of a time in which the ready posture is detected, the exercise posture of the user by applying the joint feature point information to an exercise posture learning model.

According to another embodiment of the present disclosure, there is provided an apparatus for learning an exercise posture of a user. The apparatus comprising: at least one storage medium; and at least one processor, wherein the at least one processor is configured to: check joint feature point information that is constructed based on a joint of the user, learn a ready posture learning model by learning the joint feature point information corresponding to the ready posture of the user, and learn an exercise posture learning model by learning the joint feature point information corresponding to the exercise posture of the user.

According to another embodiment of the present disclosure, there is provided an apparatus for checking an exercise posture of a user. The apparatus comprising: at least one storage medium; and at least one processor, wherein the at least one processor is configured to: check joint feature point information that is constructed based on a joint of the user, detect a ready posture of the user by using a ready posture learning model, and detect, in consideration of a time in which the ready posture is detected, the exercise posture of the user by applying the joint feature point information to an exercise posture learning model.

The features briefly summarized above for this disclosure are only exemplary aspects of the detailed description of the disclosure which follow, and are not intended to limit the scope of the disclosure.

According to an embodiment of the present disclosure, a user's exercise actions like punch, kick and swing may be efficiently detected, and applied to sports like boxing, taekwondo, squash and tennis, and thus virtual experience or training may be realized.

According to an embodiment of the present disclosure, since various exercise actions may be analyzed without limitation to a specific sport, a general-purpose integrated sports platform applicable to virtual reality (VR), augmented reality (AR) and mixed reality (MR) may be constructed.

According to an embodiment of the present disclosure, it is possible to minimize a physical resource of an apparatus, to minimize data resources necessary for analysis, and to configure a method and apparatus for efficiently analyzing exercise actions.

Effects obtained in the present disclosure are not limited to the above-mentioned effects, and other effects not mentioned above may be clearly understood by those skilled in the art from the following description.

### BRIEF DESCRIPTION OF THE DRAWINGS

FIG. 1 is a block diagram showing an exercise posture learning device according to an embodiment of the present disclosure.

FIG. 2A is a view exemplifying joint feature points used in an exercise posture learning device according to an embodiment of the present disclosure.

FIG. 2B is a view exemplifying information on joint feature points used in an exercise posture learning device according to an embodiment of the present disclosure.

FIG. 2C is a view exemplifying exercise data used in an exercise posture learning device according to an embodiment of the present disclosure.

FIG. 3 is a view exemplifying a reference posture and exercise postures that are analyzed in an exercise posture learning device according to an embodiment of the present disclosure.

FIG. 4A is a block diagram showing an exercise posture checking device according to an embodiment of the present disclosure.

FIG. 4B is a block diagram showing an exercise posture checking device according to another embodiment of the present disclosure.

FIG. 5 is a flowchart showing a method for learning an exercise posture according to an embodiment of the present disclosure.

FIG. 6 is a flowchart showing a method for checking an exercise posture according to an embodiment of the present disclosure.

FIG. 7 is a block diagram exemplifying a computing system for implementing a method and device for learning an exercise posture and a method and device for checking an exercise posture in accordance with an embodiment of the present disclosure.

### DETAILED DESCRIPTION OF THE INVENTION

Hereinafter, exemplary embodiments of the present disclosure will be described in detail with reference to the accompanying drawings so that those skilled in the art may easily implement the present disclosure. However, the present disclosure may be implemented in various different ways, and is not limited to the embodiments described therein.

In describing exemplary embodiments of the present disclosure, well-known functions or constructions will not be described in detail since they may unnecessarily obscure the understanding of the present disclosure. The same constituent elements in the drawings are denoted by the same reference numerals, and a repeated description of the same elements will be omitted.

In the present disclosure, when an element is simply referred to as being “connected to”, “coupled to” or “linked to” another element, this may mean that an element is “directly connected to”, “directly coupled to” or “directly linked to” another element or is connected to, coupled to or linked to another element with the other element intervening therebetween. In addition, when an element “includes” or “has” another element, this means that one element may further include another element without excluding another component unless specifically stated otherwise.

In the present disclosure, elements that are distinguished from each other are for clearly describing each feature, and do not necessarily mean that the elements are separated. That is, a plurality of elements may be integrated in one hardware or software unit, or one element may be distributed and formed in a plurality of hardware or software units. Therefore, even if not mentioned otherwise, such integrated or distributed embodiments are included in the scope of the present disclosure.

In the present disclosure, elements described in various embodiments do not necessarily mean essential elements, and some of them may be optional elements. Therefore, an embodiment composed of a subset of elements described in an embodiment is also included in the scope of the present disclosure. In addition, embodiments including other elements in addition to the elements described in the various embodiments are also included in the scope of the present disclosure.

In the present document, such phrases as ‘A or B’, ‘at least one of A and B’, ‘at least one of A or B’, ‘A, B or C’, ‘at least one of A, B and C’ and ‘at least one of A, B or C’ may respectively include any one of items listed together in a corresponding phrase among those phrases or any possible combination thereof.

Hereinafter, embodiments of the present disclosure will be described with reference to the accompanying drawings.

FIG. 1 is a block diagram showing an exercise posture learning device according to an embodiment of the present disclosure.

Referring to FIG. 1, an exercise posture learning device according to an embodiment of the present disclosure may include a joint feature point processing unit 110, a reference posture learning unit 120, an exercise data processing unit 130, and an exercise posture learning unit 140.

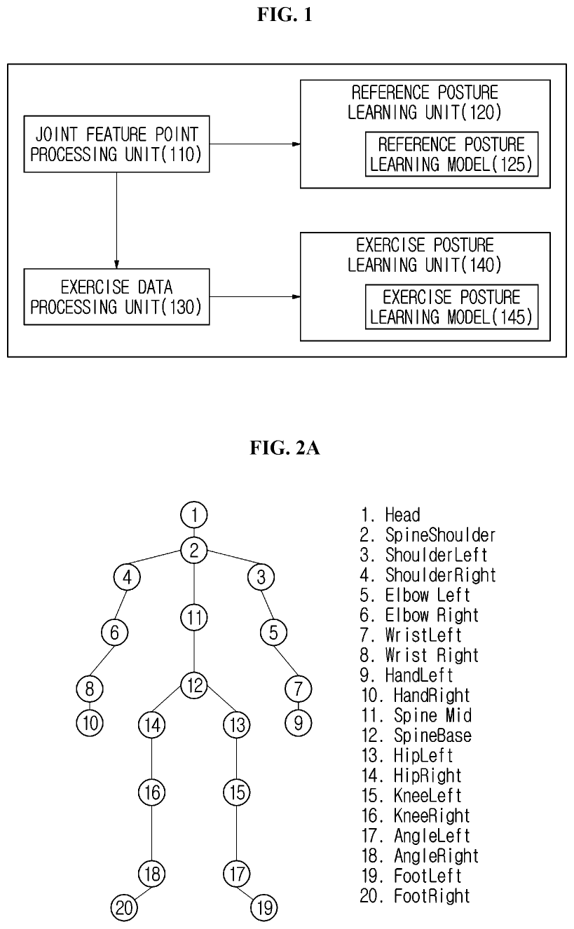

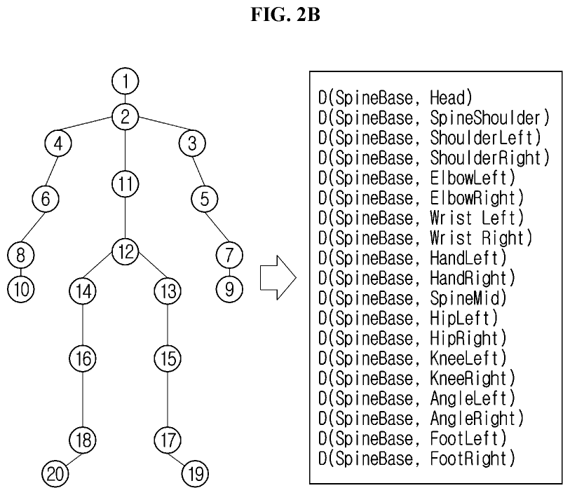

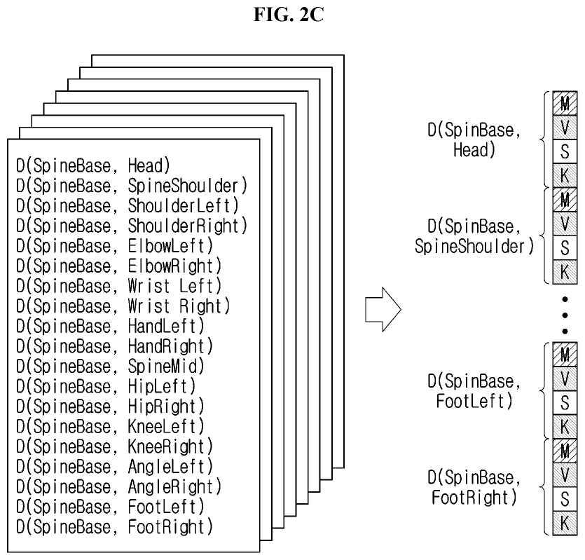

The joint feature point processing unit 110 may extract joint feature points from an input image and construct joint feature point information by combining the extracted joint feature points. As an example, the joint feature point processing unit 110 may extract joint feature points 1, 2, . . . , 20 from an input image, as exemplified in FIG. 2. As a joint feature point has a different scale according to a user's physical condition, in order to use it for recognition of an action irrespective of the user's physical condition, it is desirable that the joint feature point processing unit 110 normalizes joint feature joints. Herein, the joint feature points may include a head feature point 1 and a pelvis feature point 12, and the joint feature point processing unit 110 may check a Euclidean distance between a pelvic joint feature point (SpineBase), which corresponds to the body center of a user, and a head joint feature point (Head). In addition, the joint feature point processing unit 110 may set a distance D (SpineBase, Head) between a pelvic joint feature point (SpineBase) and a head joint feature point (Head) as a reference value (e.g., 0.4-0.5) and, based on the reference value thus set, normalize a distance between the pelvic joint feature point (SpineBase) and another joint feature point. Herein, the joint feature point processing unit 110 may readjust joint features such as the waist joint (SpineMid), the shoulder joint (SpineShoulder) and the head joint (Head) by maintaining a three-dimensional direction vector centered around the pelvis joint and reflecting a normalized scale.

Thus, by readjusting a three-dimensional position vector for the joint feature points in a user's body, the joint feature point processing unit 110 may effectively normalize information on the user's joint feature points and manage the data thus normalized as joint feature point information.

Furthermore, as there may be a plurality of joint feature points in a user's body, in order to learn data based on the plurality of joint feature points in a learning model, it is desirable that the data should be constructed as learning data with a vector form. For this, the joint feature point processing unit 110 may vectorize data about joint feature points by considering a hierarchical structure of the joint feature points. Accordingly, in an embodiment of the present disclosure, joint feature point information may be information that is constructed by vectorizing data about feature points detected from a user's body.

Meanwhile, the reference posture learning unit 120 may perform learning for the reference posture learning model 125 by inputting the above-described joint feature point information into the reference posture learning model 125 equipped with deep neural networks like a convolutional neural network and a recurrent neural network. Herein, the joint feature point information input into the reference posture learning model 125 may be information that is extracted from an image taken while a user is taking a reference posture.

Meanwhile, in order to detect an exercise posture, not only static spatial data but also spatio-temporal data reflecting a time factor needs to be constructed. Accordingly, the exercise data processing unit 130 may combine spatial data, which is provided by the joint feature point processing unit 110, and construct the data as spatio-temporal data. For example, the exercise data processing unit 130 may calculate at least one of a mean value (M), a variance value (V), a skew value (S) and a kurtosis value (K) for a distance between a pelvic joint feature point (SpineBase) and another joint feature point and then construct exercise data (refer to FIG. 2C) including spatio-temporal features by combining a calculated value. Herein, the exercise data processing unit 130 may construct exercise data by vectorizing data about each joint feature point in consideration of a hierarchical structure of joint feature points. The exercise data thus constructed may be provided to the exercise posture learning unit 140.

By using the exercise data provided by the exercise data processing unit 130, the exercise posture learning unit 140 may learn the exercise posture learning model 145 that learns an exercise posture of a user. Herein, the exercise posture learning model 145 may be equipped with deep neural networks like a convolutional neural network and a recurrent neural network.

Furthermore, generally, a user's exercise actions may occur in a sequential order of a reference posture, an exercise posture and the reference posture. For example, boxing may distinguish between all the boxing exercise actions like jab, straight, hook and upper-cut and the guard action that is a basic and reference posture, taekwondo may distinguish between exercise actions like front kick, side kick and spin kick and the ready action that is a basic and reference posture, and tennis may distinguish between exercise actions like forehand and backhand and the ready posture that is a basic and reference posture.

In consideration of what is described above, a user's exercise action may be effectively detected and recognized by detecting an exercise posture that occurs between reference postures. Accordingly, as for learning of the reference posture learning model 125 and the exercise posture learning model 145, when data corresponding to a reference posture and data corresponding to an exercise posture are distinguished for learning, the reference posture learning model 125 and the exercise posture learning model 145 may learn more accurately.

In consideration of what is described above, an exercise posture learning device may be configured to provide data about a joint feature point corresponding to a reference posture to the reference posture learning unit 120 and to provide data about a joint feature point corresponding to an exercise posture to the exercise posture learning unit 140 through the exercise data processing unit 130.

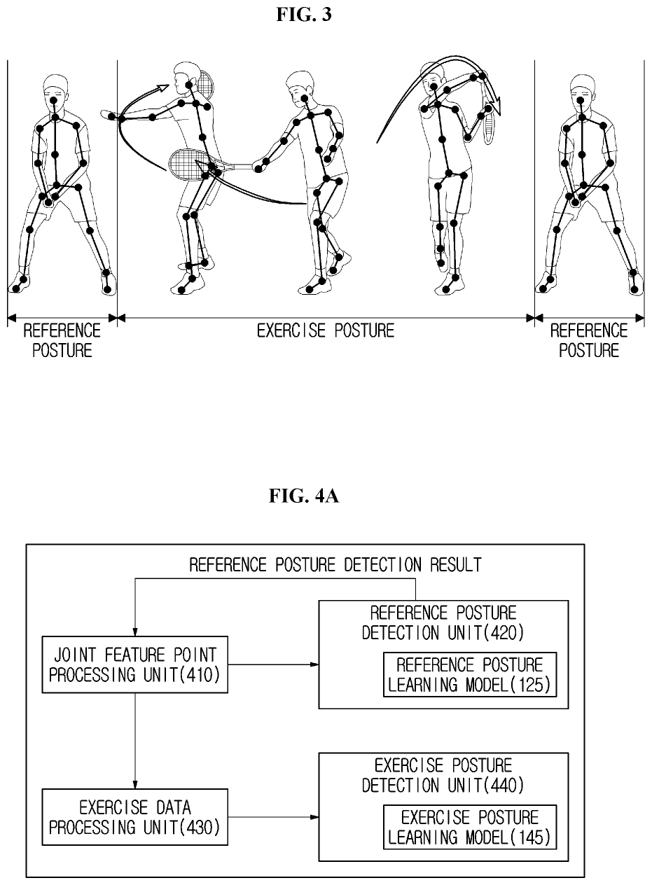

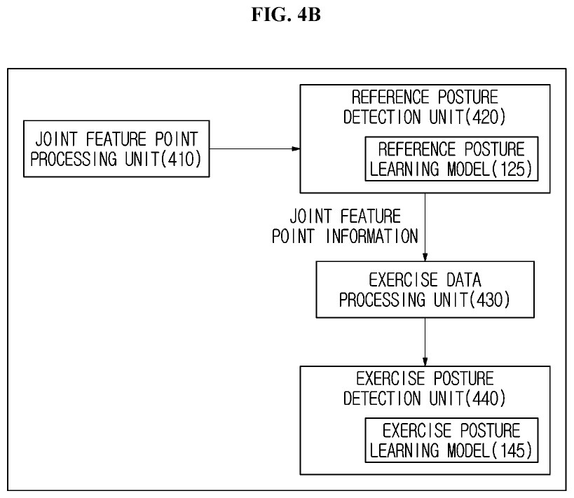

FIG. 4A is a block diagram showing an exercise posture checking device according to an embodiment of the present disclosure.

Referring to FIG. 4A, an exercise posture checking device according to an embodiment of the present disclosure may include a joint feature point processing unit 410, a reference posture detection unit 420, an exercise data processing unit 430, and an exercise posture detection unit 440.

The joint feature point processing unit 410 may extract joint feature points from an input image and construct joint feature point information by combining the extracted joint feature points. As an example, the joint feature point processing unit 410 may extract joint feature points 1, 2, . . . , 20 from an input image.

As a joint feature point has a different scale according to a user's physical condition, in order to use it for recognition of an action irrespective of the user's physical condition, it is desirable that the joint feature point processing unit 410 normalizes joint feature joints. Herein, the joint feature points may include a head feature point 1 and a pelvis feature point 12, and the joint feature point processing unit 410 may check a Euclidean distance between a pelvic joint feature point (SpineBase), which corresponds to the body center of a user, and a head joint feature point (Head). In addition, the joint feature point processing unit 410 may set a distance D (SpineBase, Head) between a pelvic joint feature point (SpineBase) and a head joint feature point (Head) as a reference value (e.g., 0.4-0.5) and, based on the reference value thus set, normalize a distance between the pelvic joint feature point (SpineBase) and another joint feature point. Herein, the joint feature point processing unit 410 may readjust joint features such as the waist joint (SpineMid), the shoulder joint (SpineShoulder) and the head joint (Head) by maintaining a three-dimensional direction vector centered around the pelvis joint and reflecting a normalized scale.

Thus, by readjusting a three-dimensional position vector for the joint feature points in a user's body, the joint feature point processing unit 410 may effectively normalize information on the user's joint feature points and manage the data thus normalized as joint feature point information.

Furthermore, as there may be a plurality of joint feature points in a user's body, in order to learn data based on the plurality of joint feature points in a learning model, it is desirable that the data should be constructed as learning data with a vector form. For this, the joint feature point processing unit 410 may vectorize data about joint feature points by considering a hierarchical structure of the joint feature points. Accordingly, in an embodiment of the present disclosure, joint feature point information may be information that is constructed by vectorizing data about feature points detected from a user's body.

Meanwhile, the reference posture detection unit 420 may be equipped with the reference posture learning model 125 that is provided in the exercise posture learning device 100 described above. Herein, the reference posture learning model 125 may be equipped with deep neural networks like a convolutional neural network and a recurrent neural network and be a model learned to receive input of joint feature point information from the joint feature point processing unit 410 and to output a result concerning whether or not a posture corresponding to the information is a reference posture. Accordingly, the reference posture detection unit 420 may input joint feature point information, which is provided by the joint feature point processing unit 410, into the reference posture learning model 125 and check whether or not a posture corresponding to the information is a reference posture.

When determining that the input joint feature point information is not a reference posture but an exercise posture, the reference posture detection unit 420 may provide the information to the joint feature point processing unit 410. Thus, the joint feature point processing unit 410 may provide the data, that is, the joint feature point information to the exercise data processing unit 430. The exercise data processing unit 430 may combine spatial data, which is provided by the joint feature point processing unit 410, and construct the data as spatio-temporal data. For example, the exercise data processing unit 430 may calculate at least one of a mean value (M), a variance value (V), a skew value (S) and a kurtosis value (K) for a distance between a pelvic joint feature point (SpineBase) and another joint feature point and then construct exercise data including spatio-temporal features by combining a calculated value. Herein, the exercise data processing unit 430 may construct exercise data by vectorizing data about each joint feature point in consideration of a hierarchical structure of joint feature points. The exercise data thus constructed may be provided to the exercise posture detection unit 440.

The exercise posture detection unit 440 may be equipped with an exercise posture learning model and output an analysis result of a user's exercise posture through an exercise posture learning model. Herein, the analysis result of the user's exercise posture may include a type of exercise, an exercise posture, detailed exercise information (speed of motion, direction of motion) and the like. As example, the exercise posture learning model may be equipped with deep neural networks like a convolutional neural network and a recurrent neural network.

Meanwhile, the reference posture detection unit 420 may keep checking whether or not input joint feature point information is a reference posture, and when the information is determined as a reference posture, provide the information thus determined to the joint feature point processing unit 410. Accordingly, the joint feature point processing unit 410 may not provide data about a joint feature point to the exercise data processing unit 430.

Although, in an embodiment of the present disclosure, the reference posture detection unit 420 notifies the joint feature point processing unit 410 concerning whether or not joint feature point information is a reference posture, and based on this, the joint feature point processing unit 410 selectively transmits data about a joint feature point to the exercise data processing unit 430, but this embodiment is not limited by the present disclosure and may be modified in various ways.

For example, the reference posture detection unit 420 may be configured to be provided between the joint feature point processing unit 410 and the exercise data processing unit 430 (refer to FIG. 4B). In this case, the reference posture detection unit 420 may be configured to check whether or not input joint feature point information is a reference posture and to selectively deliver, only when it is a reference posture, the input joint feature point information to the exercise data processing unit 430.

As described above, in an embodiment of the present disclosure, when a reference posture learning model and an exercise posture learning model are distinguished and configured to analyze a reference posture and an exercise posture, a reference posture and an exercise posture may be quickly distinguished and an exercise posture occurring between reference postures may be effectively detected, so that a user's exercise action may be recognized more quickly and accurately.

Hereinafter, embodiments of the present disclosure will be described with reference to the accompanying drawings.

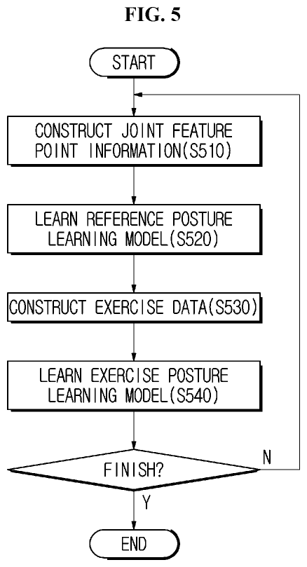

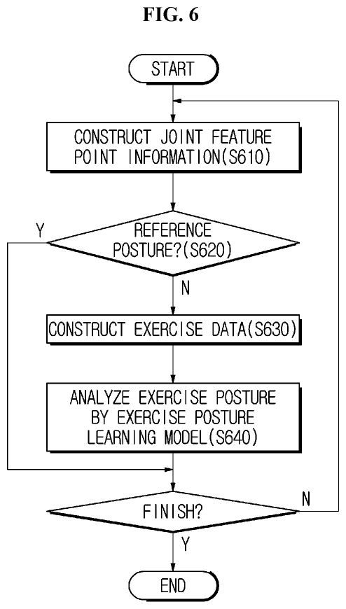

FIG. 5 is a flowchart showing a method for learning an exercise posture according to an embodiment of the present disclosure.

A method for learning an exercise posture according to an embodiment of the present disclosure may be implemented by an exercise posture learning device according to an embodiment of the present.

First, a method for learning an exercise posture according to an embodiment of the present disclosure may extract a joint feature point from an input image and construct joint feature point information by combining the extracted joint feature point (S510). As an example, an exercise posture learning device may extract joint feature points 1, 2, . . . , 20 from an input image, as exemplified in FIG. 2.

As a joint feature point has a different scale according to a user's physical condition, in order to use it for recognition of an action irrespective of the user's physical condition, it is desirable that the exercise posture learning device normalizes joint feature joints. Herein, the joint feature points may include a head feature point 1 and a pelvis feature point 12, and the exercise posture learning device may check a Euclidean distance between a pelvic joint feature point (SpineBase), which corresponds to the body center of a user, and a head joint feature point (Head). In addition, the exercise posture learning device may set a distance D (SpineBase, Head) between a pelvic joint feature point (SpineBase) and a head joint feature point (Head) as a reference value (e.g., 0.4-0.5) and, based on the reference value thus set, normalize a distance between the pelvic joint feature point (SpineBase) and another joint feature point. Herein, the exercise posture learning device may readjust joint features such as the waist joint (SpineMid), the shoulder joint (SpineShoulder) and the head joint (Head) by maintaining a three-dimensional direction vector centered around the pelvis joint and reflecting a normalized scale.

Thus, by readjusting a three-dimensional position vector for the joint feature points in a user's body, the exercise posture learning device may effectively normalize information on the user's joint feature points and manage the data thus normalized as joint feature point information.

Furthermore, as there may be a plurality of joint feature points in a user's body, in order to learn data based on the plurality of joint feature points in a learning model, it is desirable that the data should be constructed as learning data with a vector form. For this, the exercise posture learning device may vectorize data about joint feature points by considering a hierarchical structure of the joint feature points. Accordingly, in an embodiment of the present disclosure, joint feature point information may be information that is constructed by vectorizing data about feature points detected from a user's body.

Next, the exercise posture learning device may perform learning for a reference posture learning model by inputting the above-described joint feature point information into the reference posture learning model equipped with deep neural networks like a convolutional neural network and a recurrent neural network (S520). Herein, the joint feature point information input into the reference posture learning model may be information that is extracted from an image taken while a user is taking a reference posture.

Meanwhile, in order to detect an exercise posture, not only static spatial data but also spatio-temporal data reflecting a time factor needs to be constructed. Accordingly, the exercise action learning device may combine spatial data and construct the data as spatio-temporal data (S530). For example, the exercise posture learning device may calculate at least one of a mean value (M), a variance value (V), a skew value (S) and a kurtosis value (K) for a distance between a pelvic joint feature point (SpineBase) and another joint feature point and then construct exercise data including spatio-temporal features by combining a calculated value. Herein, the exercise posture learning device may construct exercise data by vectorizing data about each joint feature point in consideration of a hierarchical structure of joint feature points.

Next, by using the above-described exercise data, the exercise posture learning device may learn an exercise posture learning model that learns an exercise posture of a user (S540). Herein, the exercise posture learning model may be equipped with deep neural networks like a convolutional neural network and a recurrent neural network. Furthermore, generally, a user's exercise actions may occur in a sequential order of a reference posture, an exercise posture and the reference posture. For example, boxing may distinguish between all the boxing exercise actions like jab, straight, hook and upper-cut and the guard action that is a basic and reference posture, taekwondo may distinguish between exercise actions like front kick, side kick and spin kick and the ready action that is a basic and reference posture, and tennis may distinguish between exercise actions like forehand and backhand and the ready posture that is a basic and reference posture.

In consideration of what is described above, a user's exercise action may be effectively detected and recognized by detecting an exercise posture that occurs between reference postures. Accordingly, as for learning of the reference posture learning model and the exercise posture learning model, when data corresponding to a reference posture and data corresponding to an exercise posture are distinguished for learning, the reference posture learning model and the exercise posture learning model may learn more accurately.

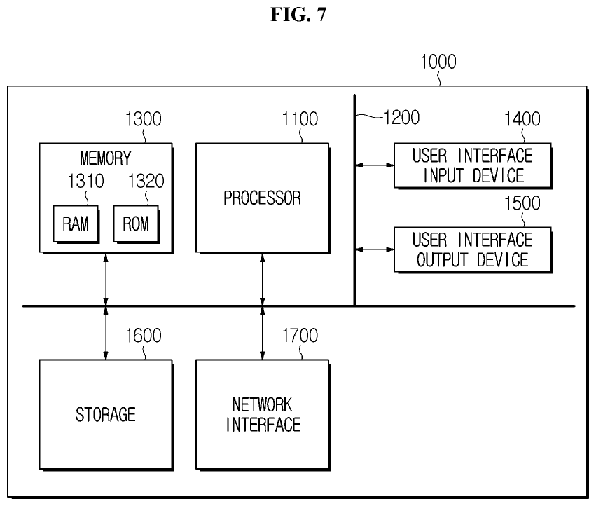

FIG. 6 is a flowchart showing a method for checking an exercise posture according to an embodiment of the present disclosure.

A method for checking an exercise posture according to an embodiment of the present disclosure may be implemented by the above-described exercise posture checking device.

First, the exercise posture checking device may extract a joint feature point from an input image and construct joint feature point information by combining the extracted joint feature point (S610). As an example, the exercise posture checking device may extract joint feature points 1, 2, . . . , 20 from an input image.

As a joint feature point has a different scale according to a user's physical condition, in order to use it for recognition of an action irrespective of the user's physical condition, it is desirable that the exercise posture checking device normalizes joint feature joints. Herein, the joint feature points may include a head feature point 1 and a pelvis feature point 12, and the exercise posture checking device may check a Euclidean distance between a pelvic joint feature point (SpineBase), which corresponds to the body center of a user, and a head joint feature point (Head). In addition, the exercise posture checking device may set a distance D (SpineBase, Head) between a pelvic joint feature point (SpineBase) and a head joint feature point (Head) as a reference value (e.g., 0.4-0.5) and, based on the reference value thus set, normalize a distance between the pelvic joint feature point (SpineBase) and another joint feature point. Herein, the exercise posture checking device may readjust joint features such as the waist joint (SpineMid), the shoulder joint (SpineShoulder) and the head joint (Head) by maintaining a three-dimensional direction vector centered around the pelvis joint and reflecting a normalized scale.

Thus, by readjusting a three-dimensional position vector for the joint feature points in a user's body, the exercise posture checking device may effectively normalize information on the user's joint feature points and manage the data thus normalized as joint feature point information.

Furthermore, as there may be a plurality of joint feature points in a user's body, in order to input data based on the plurality of joint feature points into a learning model and to detect a specific feature pattern, it is desirable that the data should be constructed in a vector form. For this, the exercise posture checking device may vectorize data about joint feature points by considering a hierarchical structure of the joint feature points. Accordingly, in an embodiment of the present disclosure, joint feature point information may be information that is constructed by vectorizing data about feature points detected from a user's body.

Meanwhile, the exercise posture checking device may be equipped with the reference posture learning model 125 that is provided in the exercise posture learning device 100 described above. Herein, the reference posture learning model 125 may be equipped with deep neural networks like a convolutional neural network and a recurrent neural network and be a model learned to receive joint feature point information as input and to output a result concerning whether or not a posture corresponding to the information is a reference posture. Accordingly, the exercise posture checking device may input joint feature point information into the reference posture learning model 125 and check whether or not a posture corresponding to the information is a reference posture (S620).

The exercise posture checking device may be configured not to perform an exercise posture analysis, when the joint feature point information is determined as a reference posture (S620—Y).

When the input joint feature point information is determined not as a reference posture but as an exercise posture (S620—N), the exercise posture checking device may construct the data, which is the joint feature point information constructed as spatial data, as spatio-temporal data (S630). For example, the exercise posture checking device may calculate at least one of a mean value (M), a variance value (V), a skew value (S) and a kurtosis value (K) for a distance between a pelvic joint feature point (SpineBase) and another joint feature point and then construct exercise data including spatio-temporal features by combining a calculated value. Herein, the exercise posture checking device may construct exercise data by vectorizing data about each joint feature point in consideration of a hierarchical structure of joint feature points.

The exercise posture checking device may be equipped with an exercise posture learning model and output an analysis result of a user's exercise posture through an exercise posture learning model. Herein, the analysis result of the user's exercise posture may include a type of exercise, an exercise posture, detailed exercise information (speed of motion, direction of motion) and the like. As example, the exercise posture learning model may be equipped with deep neural networks like a convolutional neural network and a recurrent neural network.

In consideration of what is described above, exercise data may be input into the exercise posture learning model, and an analysis result of an exercise posture may be output by the exercise posture learning model (S640).

As described above, in an embodiment of the present disclosure, when a reference posture learning model and an exercise posture learning model are distinguished and configured to analyze a reference posture and an exercise posture, a reference posture and an exercise posture may be quickly distinguished and an exercise posture occurring between reference postures may be effectively detected, so that a user's exercise action may be recognized more quickly and accurately.

FIG. 7 is a block diagram exemplifying a computing system for implementing a method and device for learning an exercise posture and a method and device for checking an exercise posture in accordance with an embodiment of the present disclosure.

Referring to FIG. 7, a computing system 1000 may include at least one processor 1100, a memory 1300, a user interface input device 1400, a user interface output device 1500, a storage 1600, and a network interface 1700, which are connected through a bus 1200.

The processor 1100 may be a semi-conductor device executing the processing of commands stored in a central processing unit (CPU) or the memory 1300 and/or the storage 1600. The memory 1300 and the storage 1600 may include various types of volatile or non-volatile storage media. For example, the memory 1300 may include a read only memory (ROM) and a random access memory (RAM).

Accordingly, steps of a method or an algorithm described in relation to embodiments of the present disclosure may be directly implemented by hardware, which is executed by the processor 1100, a software module, or a combination of these two. A software module may reside in a storage medium (that is, the memory 1300 and/or the storage 1600) like RAM, flash memory, ROM, EPROM, EEPROM, register, hard disk, removable disk, and CD-ROM. An exemplary storage medium is coupled with the processor 1100, and the processor 1100 may read information from a storage medium and may write information into a storage medium. In another method, a storage medium may be integrated with the processor 1100. A processor and a storage medium may reside in an application-specific integrated circuit (ASIC). An ASIC may reside in a user terminal. In another method, a processor and a storage medium may reside in a user terminal as individual components.

While the exemplary methods of the present disclosure described above are represented as a series of operations for clarity of description, it is not intended to limit the order in which the steps are performed, and the steps may be performed simultaneously or in different order as necessary. In order to implement the method according to the present disclosure, the described steps may further include other steps, may include remaining steps except for some of the steps, or may include other additional steps except for some of the steps.

The various embodiments of the present disclosure are not a list of all possible combinations and are intended to describe representative aspects of the present disclosure, and the matters described in the various embodiments may be applied independently or in combination of two or more.

In addition, various embodiments of the present disclosure may be implemented in hardware, firmware, software, or a combination thereof. In the case of implementing the present invention by hardware, the present disclosure can be implemented with application specific integrated circuits (ASICs), Digital signal processors (DSPs), digital signal processing devices (DSPDs), programmable logic devices (PLDs), field programmable gate arrays (FPGAs), general processors, controllers, microcontrollers, microprocessors, etc.

The scope of the disclosure includes software or machine-executable commands (e.g., an operating system, an application, firmware, a program, etc.) for enabling operations according to the methods of various embodiments to be executed on an apparatus or a computer, a non-transitory computer-readable medium having such software or commands stored thereon and executable on the apparatus or the computer.

What is claimed is:

1. A method for learning an exercise posture of a user, the method comprising:
checking joint feature point information which is constructed based on a joint of the user;
learning a ready posture learning model by learning the joint feature point information corresponding to a ready posture of the user; and
learning an exercise posture learning model by learning the joint feature point information corresponding to an exercise posture of the user.

2. The method of claim 1, wherein the joint feature point information includes feature point data that has at least one of a feature point identifier for identifying a feature point in the user's body, a distance between feature points of the body, a three-dimensional position vector between feature points of the body, and a three-dimensional direction vector between feature points of the body.

3. The method of claim 1, wherein the checking of the joint feature point information comprises normalizing the joint feature point information based on a relation between a pelvic joint feature point and a head feature point.

4. The method of claim 1, wherein the checking of the joint feature point information further comprises:
constructing vector data by arranging distance information between a pelvic joint feature point and a joint feature point: and
constructing the joint feature point information based on the vector data.

5. The method of claim 4, wherein the learning of the exercise posture learning model learns the exercise posture learning model by using, based on the distance information between the pelvic joint feature point and the joint feature point, at least one of a mean value, a variance value, a skew value and a kurtosis value for the joint feature point.

6. The method of claim 4, wherein the learning of the exercise posture learning model further comprises:
constructing vector data including at least one of a mean value, a variance value, a skew value and a kurtosis value for the joint feature point; and
learning the exercise posture learning model by using the vector data including at least one of the mean value, the variance value, the skew value and the kurtosis value for the joint feature point.

7. A method for checking an exercise posture of a user, the method comprising:
checking joint feature point information that is constructed based on a joint of the user;
detecting a ready posture of the user by using a ready posture learning model; and
detecting, in consideration of a time in which the ready posture is detected, the exercise posture of the user by applying the joint feature point information to an exercise posture learning model.

8. The method of claim 7, wherein the detecting of the exercise posture comprises inputting the joint feature point information into the exercise posture learning model

9. The method of claim 7, wherein the joint feature point information includes feature point data that has at least one of a feature point identifier for identifying a feature point in the user's body, a distance between feature points of the body, a three-dimensional position vector between feature points of the body, and a three-dimensional direction vector between feature points of the body.

10. The method of claim 7, wherein the checking of the joint feature point information comprises normalizing the joint feature point information based on a relation between a pelvic joint feature point and a head feature point.

11. The method of claim 7, wherein the checking of the joint feature point information further comprises:
constructing vector data by arranging distance information between a pelvic joint feature point and a joint feature point; and
constructing the joint feature point information based on the vector data.

12. The method of claim 11, wherein, based on the distance information between the pelvic joint feature point and the joint feature point, the detecting of the exercise posture of the user inputs at least one of a mean value, a variance value, a skew value and a kurtosis value for the joint feature point into the exercise posture learning model and checks the exercise posture that is determined by the exercise posture learning model.

13. The method of claim 8, wherein the detecting of the exercise posture of the user further comprises:
constructing vector data including at least one of a mean value, a variance value, a skew value and a kurtosis value for the joint feature point; and
inputting the vector data including at least one of the mean value, the variance value, the skew value and the kurtosis value for the joint feature point into the exercise posture learning model.

14. An apparatus for learning an exercise posture of a user, the apparatus comprising:
at least one storage medium; and
at least one processor,
wherein the at least one processor is configured to:
check joint feature point information that is constructed based on a joint of the user,
learn a ready posture learning model by learning the joint feature point information corresponding to the ready posture of the user, and
learn an exercise posture learning model by learning the joint feature point information corresponding to the exercise posture of the user.

15. An apparatus for checking an exercise posture of a user, the apparatus comprising:
at least one storage medium; and
at least one processor,
wherein the at least one processor is configured to:
check joint feature point information that is constructed based on a joint of the user,
detect a ready posture of the user by using a ready posture learning model, and
detect, in consideration of a time in which the ready posture is detected, the exercise posture of the user by applying the joint feature point information to an exercise posture learning model.
